(19) United States
(12) Patent Application Publication
(10) Pub. No.: US 2005/0045106 A1
(43) Pub. Date: Mar. 3, 2005

(54) Electrostatic chuck having a low level of particle generation and method of fabricating same

(76) Inventors: Wendell G. Boyd JR., Morgan Hill, CA (US); Jose-Antonio Marin, San Jose, CA (US); Ho T. Fang, San Jose, CA (US)

Correspondence Address: MOSER, PATTERSON & SHERIDAN, LLP;APPLIED MATERIALS INC, 595 SHREWSBURY AVE, SUITE 100, SHREWSBURY, NJ, 07702, US

(21) Appl. No.: 10/955,422

(22) Filed: Sep. 30, 2004

Related U.S. Application Data
(62) Division of application No. 10/247,499, filed on Sep. 19, 2002.

(51) Int. Cl. C23C 16/00

(52) U.S. Cl. 118/728

(57) ABSTRACT

An electrostatic chuck having either a conformal or non-conformal upon a surface for supporting a substrate. The coating reduces a of particles generated by the electrostatic chuck.

### CROSS-REFERENCE TO RELATED APPLICATIONS

This application is a divisional application of co-pending U.S. patent application Ser. No. 10/247,499, filed Sep. 19, 2002, which is incorporated by reference herein.

### FIELD OF THE INVENTION

The present invention generally relates to a substrate support chuck for supporting a workpiece, such as a semiconductor wafer, within a semiconductor wafer processing system. More specifically, the invention relates to an electrostatic chuck for electrostatically clamping a semiconductor wafer to the surface of the chuck during processing of the wafer.

### DESCRIPTION OF THE RELATED ART

Electrostatic chucks are used to retain semiconductor wafers, or other workpieces, in a stationary position during processing within semiconductor wafer processing systems. The electrostatic chucks provide more uniform clamping and better utilization of the surface of a wafer than mechanical chucks and can operate in vacuum chambers where the vacuum chucks cannot be used. An electrostatic chuck contains a chuck body having one or more electrodes within the body. The chuck body is typically formed from aluminum nitride, alumina doped with metal oxide such as titanium oxide (TiO₂), or other ceramic material with similar mechanical and resistive properties. In use, a wafer is clamped to a support surface of the electrostatic chuck as a chucking voltage is applied to the electrodes. The support surface may have groves, mesas, openings, recessed regions, and the like features that may be coated with polyimide, alumina, aluminum-nitride, and similar dielectric materials.

A backside of the clamped wafer has a physical contact with the support surface of the electrostatic chuck. The contact between the wafer and the support surface of an electrostatic chuck results in generation of particles that contaminate processing chambers of the semiconductor wafer processing system. Furthermore, movement of the wafer relative to the support surface of the chuck may also result in generation of the particles. Such movements always happen during the chucking or dechucking routine, cycles of heating or cooling of the wafer (for example, due to a difference in coefficients of thermal expansion of materials of the wafer and the chuck body), and the like occurrences.

Another source of the particle generation is defects of the support surface of an electrostatic chuck. In prior art, either the support surface or dielectric coating(s) on the support surface generally contains defects such as micro cracks, pinholes, and pores. These defects accumulate particles that become embedded into the support surface during a manufacturing process (e.g., lapping, grinding, polishing, and the like) or during maintenance of the electrostatic chuck. In use, during wafer processing, these particles are also released into a semiconductor wafer processing system.

The particles generated or released from the electrostatic chuck contaminate wafers and damage devices on the wafers. Yield losses from the particles of either origin is a major limitation in achieving higher productivity during manufacture of the semiconductor devices.

Therefore, there is a need in the art for an electrostatic chuck having a low level of particle generation.

### SUMMARY OF THE INVENTION

The present invention generally is an electrostatic chuck having a low level of particle generation and a method of fabricating the chuck using a non-conformal coating of poly-para-xylylene applied to a wafer support surface of the chuck or a conformal coating of diamond-like carbon material applied to the wafer support surface of the chuck. The coating conceals the particles embedded in the support surface of the chuck and reduces the number of the particles generated during a physical contact between the wafer and the chuck. A surface of the non-conformal coating has a roughness that is less than a roughness of the underlying wafer support surface. In alternative embodiments, the edges of the support surface, mesas, and other features having a physical contact with the wafer are rounded or smoothened prior to coating.

### BRIEF DESCRIPTION OF THE DRAWINGS

The teachings of the present invention can be readily understood by considering the following detailed description in conjunction with the accompanying drawings, in which:

FIG. 1 depicts a vertical cross-sectional view of an example a first embodiment of an electrostatic chuck of the present invention;

FIG. 1A depicts a detailed cross-sectional view of region 1A of FIG. 1;

FIG. 1B depicts a detailed cross-sectional view of region 1B of FIG. 1;

FIG. 2 depicts a top plan view of an illustrative pattern of the mesas of a second embodiment of an electrostatic chuck of the present invention;

FIG. 3 depicts a vertical cross-sectional view of an example of a second embodiment of the electrostatic chuck of FIG. 2;

FIG. 3A depicts a detailed cross-sectional view of region 3A of FIG. 3;

FIG. 3B depicts a cross-sectional view of an alternative embodiment in accordance with the present invention;

FIG. 3C depicts a cross-sectional view of an alternative embodiment of the present invention; and

FIG. 4 depicts an exemplary application for an electrostatic chuck of the present invention within an ion implanter semiconductor wafer processing system.

To facilitate understanding, identical reference numerals have been used, where possible, to designate identical elements that are common to the figures.

It is to be noted, however, that the appended drawings illustrate only typical embodiments of this invention and are therefore not to be considered limiting of its scope, for the invention may admit to other equally effective embodiments.

### DETAILED DESCRIPTION

The present invention generally is an electrostatic chuck having a low level of particle generation and a method of fabricating the chuck. The inventive electrostatic chuck comprises a non-conformal coating of dielectric material that is applied to a wafer support surface of the chuck. The non-conformal coating is formed from a polymeric material such as poly-para-xylylene (e.g., PARYLENE C) readily available from Union Carbide Corporation, Danbury, Conn., Advanced Coatings of Rancho Cucamonga, Calif., among other suppliers. Such materials have a very low permeability to moisture and other corrosive gases. The surface of the non-conformal coating generally has no micro cracks, pinholes, pores, and the like. In general terms, the non-conformal coating adheres to a relatively rough underlying surface (for example, support surface of the electrostatic chuck) and has a surface that is a much smoother than the underlying surface. Furthermore, the non-conformal coating effectively “buries” the particles embedded into the defects of the support surface thus preventing them from release into a semiconductor wafer processing system during use of the chuck. The non-conformal coating may be applied using conventional methods such as vacuum deposition.

In a second embodiment of the invention, a conformal coating of dielectric material is applied to the wafer support surface of the chuck. The conformal coating is formed from diamond-like carbon available from Diamonex Coating of Allentown, Pa. The diamond-like carbon-material has a low coefficient of friction and is very durable. As such, this coating minimizes particle generation and mitigates the probability of scratching the backside of a wafer.

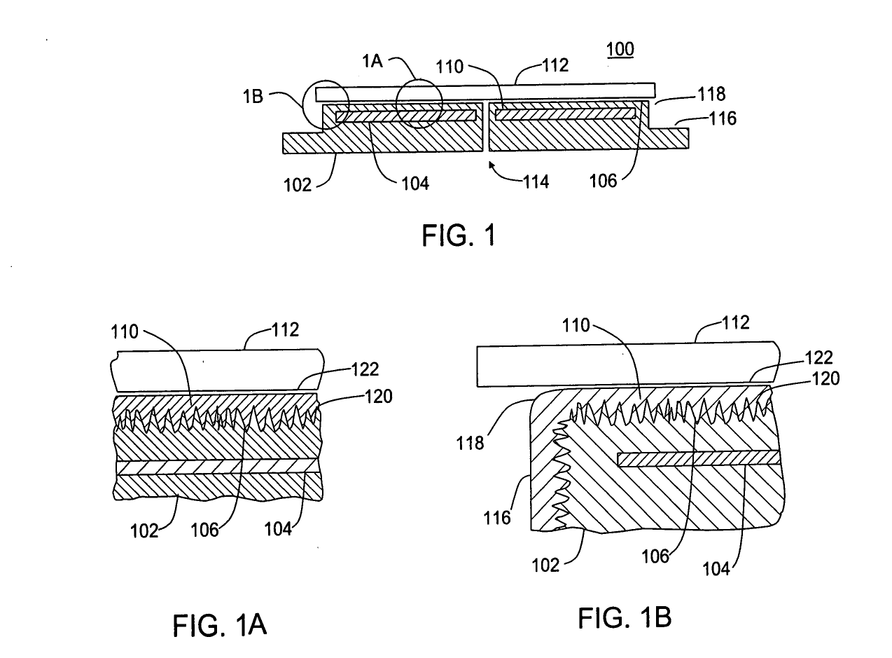

FIG. 1 is a vertical cross-sectional view of an example a first embodiment of an electrostatic chuck 100 of the present invention and FIGS. 1A, 1B provides a detailed cross-sectional view of regions 1A, 1B of FIG. 1, respectively. For best understanding of this embodiment, the reader should refer simultaneously to FIG. 1 and FIGS. 1A, 1B. The cross-sectional view in FIG. 1 is taken along a centerline. The chuck 100 comprises a chuck body 102 having embedded electrodes 104, a support surface 106, a non-conformal coating 110 of a dielectric material, a side wall surface 116, a peripheral edge 118, and an optional conduit 114. The body 102 may comprise a plurality of the conduits 114 that are formed in the chuck body 102 to provide access for the backside gas to a backside of the wafer 112, openings for the lift pins, and the like purposes. To block the backside gas from escaping, the support surface 106 may have a continuous raised plateau (not shown) around the edge 118 to seal the space between the wafer 112 and the support surface 106. The support surface 106 may comprise other features such as grooves, openings, recessed or raised regions, and the like (not shown). Use of such features for improvements in chucking, dechucking, backside heating and cooling of the wafer 112 is known in the art.

The support surface 106 generally is a flat surface, however, it may be convex or concave to adapt substantially to the wafer 112. In FIG. 1 and FIGS. 1A, 1B, the coating 110 is arbitrarily depicted as extended over the peripheral edge 118 to the side wall surface 116. In such optional embodiment, the coating 110 “buries” the defects of the chuck body 102 that may comprise the embedded particles. In one embodiment, the layer 110 is formed from poly-para-xylylene (available from Union Carbide Corporation under the name PARYLENE C). The non-conformal layer 110 has an inner surface 120 and an outer surface 122. The inner surface 120 adheres to the underlying support surface 106 and has the same roughness as the surface 106. However, the outer surface 122 is much smoother (i.e., has a lower roughness such as of about 0.2-0.01 RA μm) than the support surface 106. As such, the dielectric coating is deemed “non-conformal” because the outer surface of the coating that supports the wafer does not conform to the roughness of the underlying support surface of the chuck. Subsequently, when in use, contact between the wafer 112 and the outer surface 122 generates fewer particles than the contact between the wafer 112 and the support surface 106 would generate. To further reduce particle generation during use of the electrostatic chuck 100, the entire coating 110 or its regions along the peripheral edge 118, the edge(s) of the conduit(s) 114 and other features having a physical contact with the backside of the wafer 112 may be rounded or smoothened (not shown) using a chemical etching, mechanical polishing or (CMP), laser melt, and the like process.

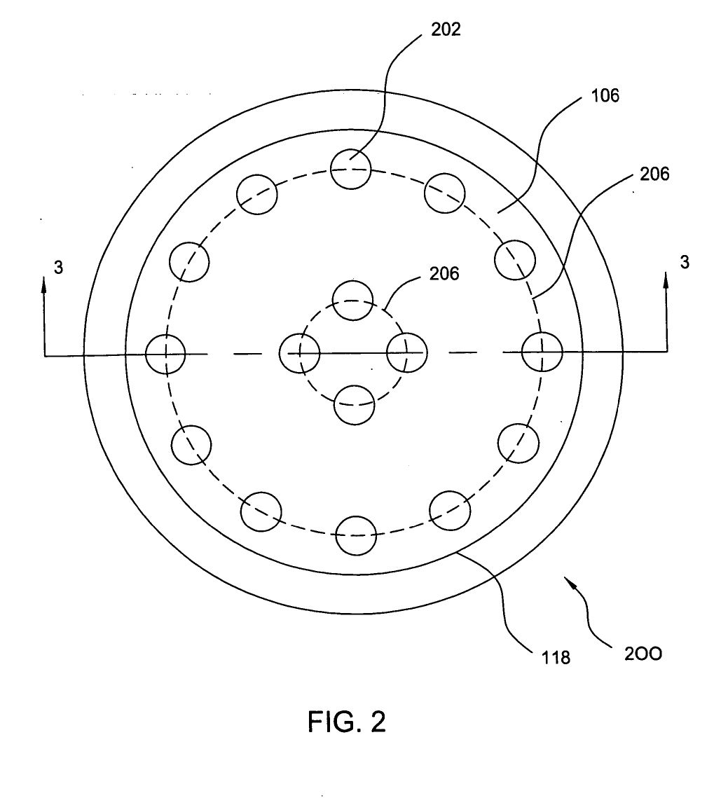

FIG. 2 is a top plan view of an illustrative pattern for the support surface 106 of an example of a second embodiment of the present invention. In this embodiment, the support surface 106 of the electrostatic chuck 200 comprises a plurality of mesas 202 that support the wafer 112 or other workpiece in a spaced-apart relation relative to the support surface 106. A distance between the backside surface of the wafer 112 and the support surface 106 is defined by a thickness of the mesas. The mesas can be judiciously positioned on the support surface 106 for improvements in performance of the electrostatic chuck such as chucking, dechucking, wafer temperature control, and the like. In FIG. 2, the mesas 202 are depicted as being positioned along the concentric circles 204 and 206. Generally, the mesas 202 are formed as individual pads having a thickness between 5 and 350 μm and dimensions in the plan view between 0.5 and 5 mm. However, mesas that are formed in shapes other than circular pads and having either vertical or sloped walls are known in the art. The mesas are generally formed from the same material as the chuck body, e.g., AlN. Alternatively, the mesas may be formed of other materials such as Si₃N₄, SiO₂, Al₂O₃, Ta₂0₅, SiC, polyimide, and the like. Methods of fabrication of the mesas are disclosed in the commonly assigned U.S. Pat. No. 5,903,428, issued May 11, 1999.

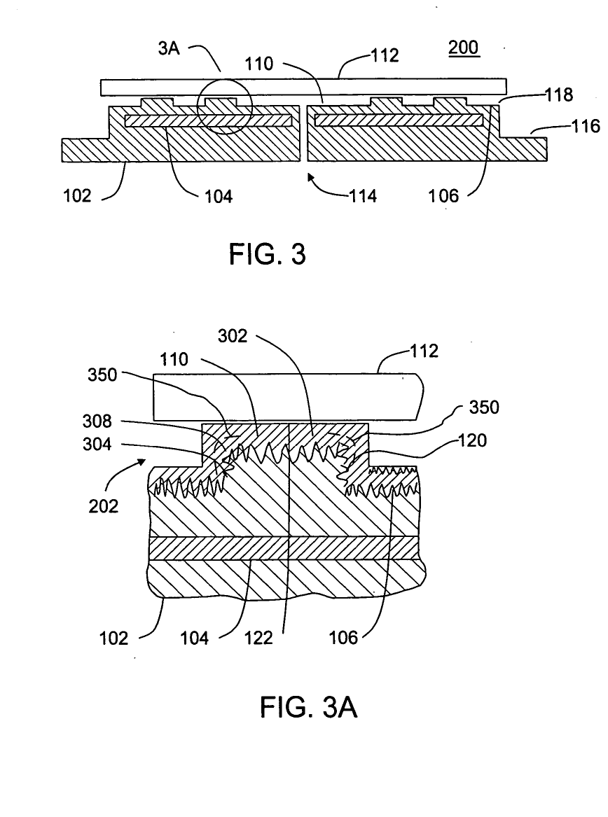

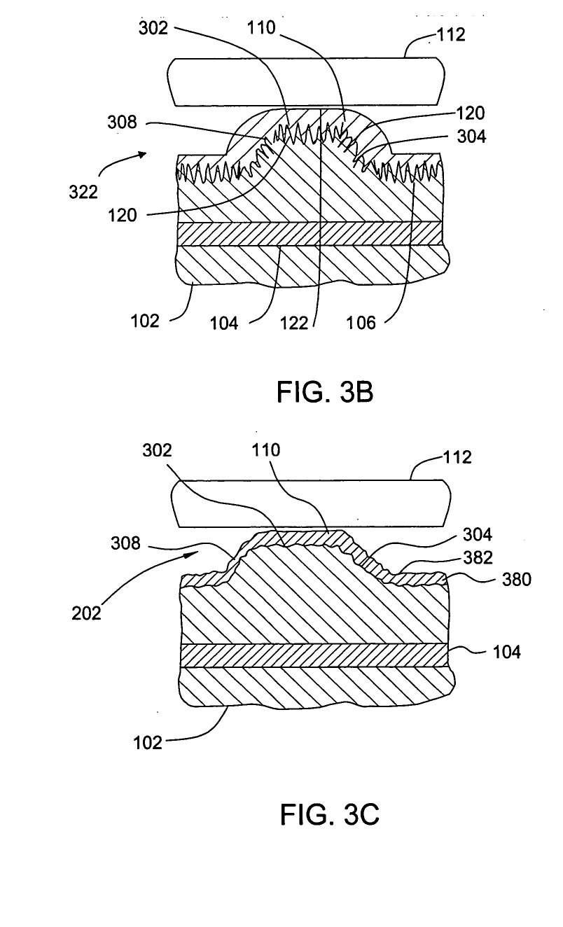

FIG. 3 depicts a vertical cross-sectional view of an electrostatic chuck 200 of FIG. 2 and FIG. 3A provides a detailed cross-sectional view of region 3A of FIG. 3. For best understanding of this embodiment of the invention, the reader should refer simultaneously to FIG. 3 and FIG. 3A. The cross sectional view in FIG. 3 is taken along a centerline 3-3 of FIG. 2. In this embodiment, the non-conformal layer 110 is formed over the mesas 202 having an upper surface 302 that retains the wafer 112, a wall surface 304, and an edge 308. By way of example, in FIG. 3 and FIG. 3A, the mesas 202 are depicted as having generally a flat upper surface 302 and vertical side wall 304. Other shapes of side walls or surfaces may be used. The inner surface 120 of the non-conformal layer 110 conforms and adheres to the underlying surfaces 106, 302, and 304 and has the same roughness as these surfaces. To enhance adhesion of the non-conformal layer 110 to the underlying surfaces 106, 302, and 304, the surfaces 106, 302 and 304 may be plasma cleaned prior to applying the coating. The outer surface 122 of the non-conformal layer 110 is much smoother than the surfaces 106, 302, and 304. Specifically, a portion of the non-conformal layer 110 that is located on the upper surface 302 of the mesa 202 has less roughness then the underlying upper surface 302. Subsequently, in use, a contact between the wafer 112 and the mesa 202 having the coating 110 generates fewer particles than the contact between the wafer 112 and the upper surface 302 would generate. To further reduce particle generation during use of the electrostatic chuck 200, the entire coating 110 or its regions along the peripheral edge 118, the edges 308, the edge(s) of the conduit(s) 114 and other features having a physical contact with the back side of the wafer 112 may be rounded or smoothened (as indicated by a dashed line 350) using a chemical etching, laser melting, mechanical polishing or (CMP), and the like process.

FIG. 3B depicts a cross-sectional view of an alternative embodiment of an example of the present invention. In this embodiment, the edge 308 of one or more of the mesas 322 is deliberately rounded or smoothened prior to application of the non-conformal layer 110. In further embodiment, the entire upper surface of the mesa 322 may be rounded or smoothened (not shown). The edge 308 of the mesa 322 may be shaped using a computer-controlled router with a diamond-coated head, chemical etching, grinding, grit blasting, and the like process. Similarly, a roughness of the outer surface 122 may be further reduced using chemical etching, mechanical polishing or (CMP), and the like process. In use, the electrostatic chuck of this embodiment of the invention provides more comprehensive reduction in a number of particles that are generated during a contact between the wafer 114 and the upper surface 122 than a chuck having the mesas with sharper edges.

In any of the exemplary embodiments, a non-conformal coating is formed from a poly-para-xylylene and applied to a support surface of the electrostatic chuck that is adapted to retain the 12″ (300 mm) wafers. The chuck body is fabricated from a ceramic material such as aluminum nitride. The support surface has a roughness of about 0.2-0.01 RA μm. The coating is applied using a vacuum deposition process to a thickness between 5 and 100 μm.

Having generally no defects such as micro cracks, pinholes, pores and the like, the poly-para-xylylene coating conceals the particles that have been embedded in the defects of the support surface during fabrication of the electrostatic chuck or prior to application of the non-conformal coating of the present invention. Therefore, these “buried” particles are blocked from penetration into processing chambers of a semiconductor wafer processing system. Defects in the support surface of an electrostatic chuck may also accumulate particles during routine maintenance of the chuck (for example, chemical and/or mechanical cleaning from the deposits and sub-products of wafer processing). However, a surface of the poly-para-xylylene coating has so low roughness that the coating does not retain the loose particles that the maintenance procedures may generate. Therefore, the poly-para-xylylene coating reduces a number of particles generated in use by the electrostatic chuck during a physical contact, relative movements between the support surface and the wafer, and during the chuck maintenance procedures.

A poly-para-xylylene coating is stable in a broad range of temperatures and in most of the plasma and non-plasma environments that an electrostatic chuck can be exposed to in a semiconductor wafer processing system. Similarly, the coating is compatible with means used to control a temperature of the chucked wafers such as backside heaters or gases, infra-red (IR) or ultra-violet (UV) irradiation, and the like. The coating creates a strong bond with the ceramic materials used to form a body of the electrostatic chuck (e.g., aluminum nitride, alumina doped with metal oxide such as titanium oxide (TiO₂), and the like). Such bond forms with either flat, convex, or concave surfaces and with features having sharp edges (e.g., mesas, grooves, openings, and the like). The poly-para-xylylene coating has a bulk resistivity of about (6-8)×10¹⁶ ohms that is about 10²-10⁶ times greater than the resistivity of other materials forming the electrostatic chuck. As such, the coating does not increase a current drawn by the electrodes of the chuck.

Alternatively, as shown in FIG. 3C, the mesas 202 (or the flat chuck surface of FIG. 1A) may be coated with a conformal coating 380. One example of a conformal coating that is both durable and has a low coefficient of friction is diamond-like carbon. Diamond-like carbon is available from Diamonex Coatings of Allentown, Pa. The durability and low coefficient of friction reduce the probability that contact between the wafer and the mesas will produce particles.

As shown in FIG. 3C, the conformal coating 380 has an inner surface 384 that conforms to and bonds with the rough surface 304 of the chuck 102. The outer surface 382 of the conformal coating 380 substantially matches the roughness of the chuck surface. As such, before coating, the mesas 202 are deburred using, for example a plasma etch. Those skilled in the art will realize that there are many techniques available for deburring or otherwise smoothing the surface of the mesas.

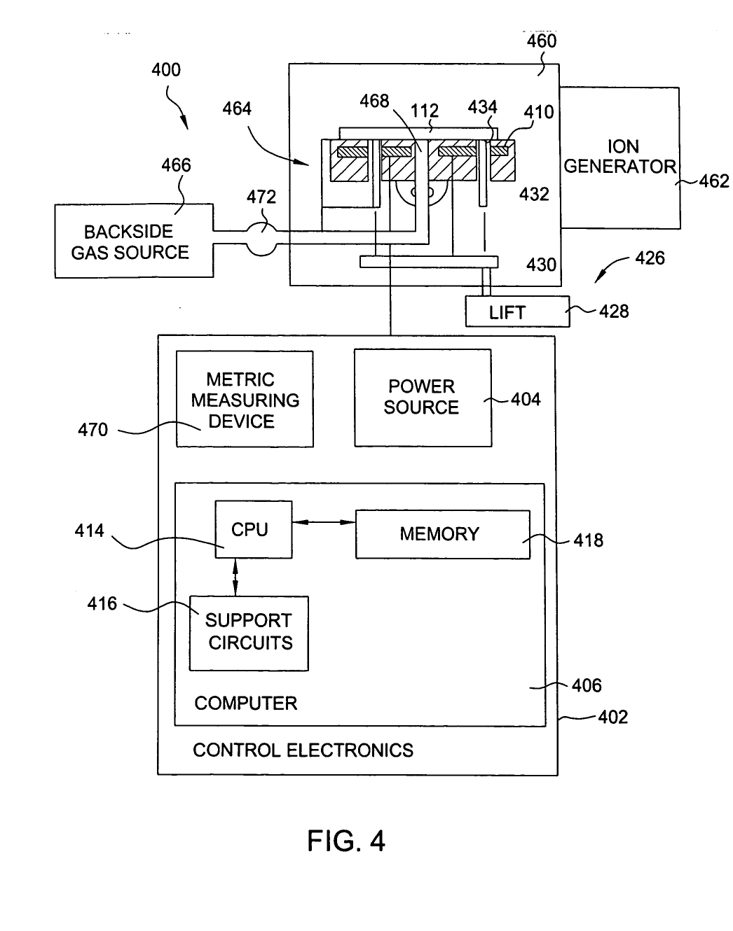

FIG. 4 depicts one particular use for the inventive electrostatic chuck to clamp a wafer within an ion implanter semiconductor wafer processing system 400. The system 400 comprises a vacuum chamber 460, an ion generator 462, an electrostatic chuck 164, a backside gas source 466, and control electronics 402. Although the invention is described in an exemplary ion implant system, the invention is generally applicable to other semiconductor wafer processing systems wherever an electrostatic chuck is used to retain a wafer within a processing chamber.

An ion beam or other source of ions for implantation that is generated by the ion generator 462 is scanned horizontally while the wafer 112 is being displaced vertically such that all locations on the wafer 112 may be exposed to the ion beam. The electrostatic chuck 464 is disposed in the chamber 460. The electrostatic chuck 464 has a pair of coplanar electrodes 410 embedded within a chuck body 412 that forms a support surface 434 upon which the electrostatic chuck 464 retains the wafer 112. The electrostatic chuck 464 produces an attraction force that is sufficient to permit the chuck to be rotated from a horizontal position to a vertical position without the wafer 112 moving across the support surface 434.

The chuck body 412 includes a passage 468 that permits a heat transfer gas or gases, such as helium, to be supplied from the backside gas source 466 to an interstitial space between the support surface 434 and the wafer 112 to promote heat transfer. The mesas can be positioned on the support surface 434, for example, to facilitate a uniform temperature across the wafer or to produce a particular temperature gradient across the wafer.

One exemplary chuck 464 used in an ion implanter is shown and discussed in U.S. patent application Ser. No. 09/820,497, filed Mar. 28, 2001, and entitled “Cooling Gas Delivery System for a Rotatable Semiconductor Substrate Support Assembly”, commonly assigned to Applied Materials, Inc. of Santa Clara, Calif., which is hereby incorporated by reference in its entirety. That patent application discloses a rotatable wafer support assembly (e.g., chuck) having a rotatable shaft coupled to the chuck and a housing disposed over the shaft. The shaft, housing, and a plurality of seals form part of a gas delivery system for providing a cooling gas (e.g., helium) to the wafer.

Another exemplary chuck 464 used in an ion implanter is shown and discussed in U.S. Pat. No. 6,207,959, entitled “ION Implanter” commonly assigned to Applied Materials, Inc. of Santa Clara, Calif., which is hereby incorporated by reference in its entirety. That patent discloses an implanter with a scanning arm assembly enabling rotation of a wafer holder (e.g., electrostatic chuck) about the wafer axis. It is noted therein that a vacuum robot is provided in the chamber for removing processed wafers from the wafer holder (e.g., chuck) and delivering new wafers to the wafer holder. As such, in this exemplary ion implanter processing system, the lift pins and their respective lift pin passageways through the chuck, as well as a lift pin actuator 428 (illustratively shown in FIG. 4), are not required in such ion implanter semiconductor wafer processing system 400.

The control circuitry 402 comprises a DC power supply 404, a metric measuring device 470, and a computer device 406. The DC power supply 404 provides a voltage to the electrodes 410 to retain (i.e., “chuck”) the wafer 112 to the surface 434 of the chuck. The chucking voltage provided by the power source 404 is controlled by the computer 406. The computer 406 is a general purpose, programmable computer system comprising a central processing unit (CPU) 414 connected to conventional support circuits 416 and to memory circuits 418, such as read-only memory (ROM) and random access memory (RAM). The computer 406 is also coupled to the metric measuring device 470, which is coupled to a flow sensor 472 of the gas supplied by the backside gas source 466. The computer 406 monitors and regulates the gas flow to the chuck in response to measurement readings from the flow sensor 472.

As discussed above, in one embodiment the chuck 464 comprises a non-conformal coating of poly-para-xylylene. In an alternate embodiment, the chuck 464 is coated with a conformal coating of diamond-like carbon. Accordingly, a chuck 464 coated under either embodiments, provides a low level of particle generation without concern for the backside morphology of the wafer 112, as well as facilitating improved wafer processing. In short, the present invention brings the various advantages mentioned above to semiconductor processing systems and, in particular, to ion implanter systems.

Although various embodiments which incorporate the teachings of the present invention have been shown and described in detail herein, those skilled in the art can readily devise many other varied embodiments that still incorporate these teachings.

1. An electrostatic chuck for supporting electrostatically a workpiece, comprising:
a chuck body having a support surface to support the workpiece; and
a diamond-like carbon coating disposed upon the support surface.

2. The electrostatic chuck of claim 1 wherein said coating has a thickness between 5 and 100 micron.

3. The electrostatic chuck of claim 1 wherein the support surface comprises a plurality of mesas having a top surface and an edge and protruding from the support surface.

4. The electrostatic chuck of claim 3 wherein the edge of a mesa is rounded.

5. The electrostatic chuck of claim 1 wherein said coating is a conformal coating.

6. A method of fabricating an electrostatic chuck for supporting electrostatically a workpiece, comprising the steps of:
supplying an electrostatic chuck having a support surface; and
depositing a coating of diamond-like carbon upon the support surface.

7. The electrostatic chuck of claim 6 wherein said coating has a thickness between 5 and 100 micron.

8. The electrostatic chuck of claim 6 wherein the support surface comprises a plurality of mesas having a top surface and an edge and protruding from the support surface.

9. The electrostatic chuck of claim 8 wherein the edge of a mesa is rounded.

10. A system for processing semiconductor wafers comprising:
a process chamber;
a substrate support pedestal, positioned within said process chamber for supporting a substrate for a processing within said process chamber, wherein said substrate support pedestal comprises an electrostatic chuck having a support surface and a coating of diamond-like carbon upon the support surface.

11. The system of claim 10 wherein said process chamber further comprises an ion beam source of ions and adapted for performing an ion implantation process upon the substrate.

12. The system of claim 10 wherein said coating has a thickness between 5 and 100 micron.

13. The system of claim 10 wherein a roughness of a surface of said coating is lower than a roughness of the support surface.

14. The system of claim 10 wherein the support surface comprises a plurality of mesas having a top surface and an edge and protruding from the support surface.

15. The system of claim 14 wherein the edge of a mesa is rounded.
